(19) United States
(12) Patent Application Publication
(10) Pub. No.: US 2024/0389307 A1
(43) Pub. Date: Nov. 21, 2024

(54) FABRICATION METHOD OF SEMICONDUCTOR DEVICE, SEMICONDUCTOR DEVICE AND MEMORY SYSTEM

(71) Applicant: YANGTZE MEMORY TECHNOLOGIES CO., LTD., Wuhan (CN)

(72) Inventors: Dongxue ZHAO, Wuhan (CN); Yuhui HAN, Wuhan (CN); Di WANG, Wuhan (CN); Wenxi ZHOU, Wuhan (CN); Zhiliang XIA, Wuhan (CN); Zongliang HUO, Wuhan (CN)

(21) Appl. No.: 18/458,563

(22) Filed: Aug. 30, 2023

(30) Foreign Application Priority Data
May 15, 2023 (CN) 2023105460960

(51) Int. Cl. H10B 12/00; H01L 23/00; H01L 25/00; H01L 25/065; H01L 25/18; H10B 80/00

(52) U.S. Cl. CPC H10B 12/485; H01L 24/08; H01L 24/80; H01L 25/0657; H01L 25/18; H01L 25/50; H10B 12/02; H10B 80/00; H01L 2224/08145; H01L 2224/80895; H01L 2224/80896; H01L 2924/1431; H01L 2924/1436

(57) ABSTRACT

Examples of the present disclosure disclose a fabrication method of a semiconductor device, a semiconductor device and a memory system. The method includes: providing a stack structure including a device region and a connection region arranged in a first direction, the stack structure including an interlayer insulating layer and a composite material layer alternatively stacked in a second direction, the composite material layer including a bit line in the connection region, and the second direction intersecting the first direction; forming a contact hole in the connection region, the contact hole extending to the bit line from a first side of the stack structure in the second direction; and forming a contact structure connected with bit line in the contact hole.

### CROSS-REFERENCE TO RELATED APPLICATIONS

The present application claims priority to Chinese Patent Application No. 2023105460960, which was filed May 15, 2023, is titled “FABRICATION METHOD OF SEMICONDUCTOR DEVICE, SEMICONDUCTOR DEVICE AND MEMORY SYSTEM,” and is hereby incorporated herein by reference in its entirety.

### TECHNICAL FIELD

The present disclosure relates to the field of semiconductor technology, and more particularly to a method of fabricating a semiconductor device, a semiconductor device, and a memory system.

### BACKGROUND

With an increasing demand for a memory integration level, challenges in how to fabricate the memory to improve a performance of the memory increase.

### SUMMARY

The present disclosure provides a fabrication method of a semiconductor device, a semiconductor device and a memory system that can reduce a volume of the semiconductor device, improve storage density and simplify the fabrication process.

The present disclosure provides a fabrication method of a semiconductor device including: providing a stack structure comprising a device region and a connection region arranged in a first direction, the stack structure comprising an interlayer insulating layer and a composite material layer alternatively stacked in a second direction, the composite material layer comprising a bit line in the connection region, and the second direction intersecting the first direction; forming a contact hole in the connection region, the contact hole extending to the bit line from a first side of the stack structure in the second direction; and forming a contact structure connected with the bit line in the contact hole.

In an example, the contact structure comprises a conductive layer and an isolation layer disposed around the conductive layer, wherein the conductive layer is connected with the bit line.

In an example, the conductive layer extends to the bit line from the first side of the stack structure in the second direction, and the isolation layer covers side walls of the conductive layer.

In an example, the stack structure comprises a plurality of the composite material layers, and each of the composite material layers comprises the bit line, the connection region has a plurality of the contact holes formed therein and disposed in one-to-one correspondence with a plurality of the bit lines, and each of the contact holes extends to a corresponding bit line from the first side of the stack structure in the second direction.

In an example, the method further comprises: providing a substrate, the stack structure being on a side of the substrate, and the first side of the stack structure being a side of the stack structure away from the substrate.

In an example, the method further comprises: providing a substrate, the stack structure being on a side of the substrate, wherein the forming the contact hole in the connection region comprises: removing the substrate; and forming the contact hole in the connection region, the first side of the stack structure being a side of the stack structure from which the substrate is removed.

In an example, the method further comprises: providing a gate structure in the device region, the gate structure penetrating through the stack structure in the second direction.

In an example, the method further comprises: providing a plate line in the device region, the plate line penetrating through the stack structure in the second direction and extending in a third direction and being located on a side of the gate structure away from the bit line, the third direction intersecting the second direction and the first direction.

In an example, the method further comprises: after the forming the contact structure in the contact hole, bonding a first peripheral device on the first side of the stack structure, wherein the first peripheral device is connected with the contact structure, the gate structure and the plate line, respectively.

In an example, the method further comprises: bonding a first peripheral device on the first side of the stack structure, and bonding a second peripheral device on a second side of the stack structure, wherein the second side of the stack structure is opposite the first side, the contact structure is connected with the first peripheral device, the gate structure is connected with the first peripheral device or the second peripheral device, and the plate line is connected with the first peripheral device or the second peripheral device.

In an example, the composite material layer further comprises a channel layer, a source and a drain in the device region, wherein the channel layer and the gate structure are arranged in a third direction, the third direction intersects the second direction and the first direction, the drain is located between the channel layer and the bit line, the drain is connected with the bit line, and the source is located between the channel layer and the plate line.

In an example, the gate structure comprises a gate and a gate insulating layer, wherein the gate penetrates through the stack structure in the second direction and the gate insulating layer is located between the gate and the stack structure.

In an example, the composite material layer further comprises a capacitor in the device region, wherein the capacitor is located between the plate line and the source, and is connected with the plate line and the source, respectively.

In an example, the capacitor comprises a first electrode extending in the first direction, a high dielectric constant dielectric layer disposed around the first electrode, and a second electrode disposed around the high dielectric constant dielectric layer, wherein the first electrode is connected with the plate line and the second electrode is connected with the source.

Accordingly, the present disclosure further provides a semiconductor device including: a stack structure comprising a device region and a connection region arranged in a first direction, the stack structure comprising an interlayer insulating layer and a composite material layer alternatively stacked in a second direction, the composite material layer comprising a bit line in the connection region, and the second direction intersecting the first direction; and a contact structure in the connection region, the contact structure extending to the bit line from a first side of the stack structure in the second direction and connected with the bit line.

In an example, the contact structure comprises a conductive layer and an isolation layer disposed around the conductive layer, wherein the conductive layer is connected with the bit line.

In an example, the conductive layer extends to the bit line from the first side of the stack structure in the second direction, and the isolation layer covers side walls of the conductive layer.

In an example, the stack structure comprises a plurality of the composite material layers, each of the composite material layers comprises the bit line, the semiconductor device comprises a plurality of the contact structures disposed in one-to-one correspondence with a plurality of the bit lines, and each of the contact structures extends to a corresponding bit line from the first side of the stack structure in the second direction and is connected with the corresponding bit line.

In an example, the semiconductor device further includes a gate structure in the device region, wherein the gate structure penetrates through the stack structure in the second direction.

In an example, the gate structure comprises a gate and a gate insulating layer, wherein the gate penetrates through the stack structure in the second direction, and the gate insulating layer is located between the gate and the stack structure.

In an example, the semiconductor device further includes a plate line in the device region, wherein the plate line penetrates through the stack structure in the second direction, extends in a third direction, and is located on a side of the gate structure away from the bit line, and the third direction intersects the second direction and the first direction.

In an example, the semiconductor device further includes a first peripheral device, wherein the first peripheral device is bonded on the first side of the stack structure, and the first peripheral device is connected with the contact structure, the gate structure and the plate line, respectively.

In an example, the semiconductor device further includes a first peripheral device and a second peripheral device, wherein the first peripheral device is bonded on the first side of the stack structure, the second peripheral device is bonded on a second side of the stack structure, the second side of the stack structure is opposite the first side, the contact structure is connected with the first peripheral device, the gate structure is connected with the first peripheral device or the second peripheral device, and the plate line is connected with the first peripheral device or the second peripheral device.

In an example, the composite material layer further comprises a channel layer, a source and a drain in the device region, wherein the channel layer and the gate structure are arranged in a third direction, the third direction intersects the second direction and the first direction, the drain is located between the channel layer and the bit line, the drain is connected with the bit line, and the source is located between the channel layer and the plate line.

In an example, the composite material layer further comprises a capacitor in the device region, wherein the capacitor is located between the plate line and the source, and is connected with the plate line and the source, respectively.

In an example, the capacitor comprises a first electrode extending in the first direction, a high dielectric constant dielectric layer disposed around the first electrode, and a second electrode disposed around the high dielectric constant dielectric layer, wherein the first electrode is connected with the plate line, and the second electrode is connected with the source.

The present disclosure further provides a memory system including the above-described memory and a controller electrically connected with the memory.

Examples of the present disclosure provide a fabrication method of a semiconductor device, a semiconductor device and a memory system that can provide a stack structure including a device region and a connection region arranged in a first direction and including an interlayer insulating layer and a composite material layer stacked alternatively in a second direction such that memory cells in the device region are stacked in the second direction to reduce the volume of the semiconductor device and improve the storage density. In addition, the composite material layer includes a bit line in the connection region, the contact structure is located in the connection region, and the contact structure extends to the bit line from the first side of the stack structure in the second direction and is connected with the bit line. Thus the stack structure in the connection region is fabricated without a step structure, thereby simplifying the fabrication process.

### BRIEF DESCRIPTION OF THE DRAWINGS

In order to more clearly illustrate technical solutions in examples of the present disclosure, drawings required for the description of the examples will be briefly introduced below. Drawings in the following description represent only some examples of the present disclosure and according to these drawings, other drawings can be obtained by those of ordinary skills in the art without any creative works.

FIG. 1 is a schematic flowchart illustrating a method of fabricating a semiconductor device provided by some examples of the present disclosure.

FIGS. 2a to 2h are schematic structure diagrams illustrating a method of fabricating a semiconductor device provided by some examples of the present disclosure.

FIGS. 3a to 3f are schematic structure diagrams illustrating a method of fabricating a semiconductor device provided by some examples of the present disclosure.

FIG. 4 is a partial schematic structure diagram of a semiconductor device provided by some examples of the present disclosure.

FIG. 5 is a schematic structure diagram of a semiconductor device provided by some examples of the present disclosure.

FIG. 6 is another schematic structure diagram of a semiconductor device provided by some examples of the present disclosure.

FIG. 7 is yet another schematic structure diagram of a semiconductor device provided by some examples of the present disclosure. and

FIG. 8 is a schematic structure diagram of a system with a memory device provided by some examples of the present disclosure.

### DETAILED DESCRIPTION

Details of specific structures and functions disclosed herein are representative only and are used for the purpose of describing examples of the present disclosure. The present disclosure may be practiced in many alternative forms, and is not limited to the examples described herein.

In the description of the present disclosure, an orientation or positional relationship indicated by terms “center,” “lateral direction,” “upper,” “lower,” “left,” “right,” “vertical,” “horizontal,” “top,” “bottom,” “inner” and “outer” is the orientation or positional relationship based on the drawings, and is only for the purpose of describing the present disclosure and simplifying the description. There is no indication or implication that the device or element referred to must have any particular orientation, or be constructed or operated in any particular orientation. As a result, they should not be understood as limitations for the present disclosure. Moreover, the terms “first,” “second” etc. are only used for the purpose of description and should not be understood to indicate or imply relative importance or to designate the number of the referenced technical features implicitly. Therefore, a feature defined by “first” or “second” may include one or more instances of the feature explicitly or implicitly. In the description of the present disclosure, “a plurality of” means two or more unless otherwise specified. Moreover, the terms “include.” “comprise,” or any variation thereof is intended to cover the meaning of “include or comprise non-exclusively.”

In the description of the present disclosure, the terms “interconnect” or “connection” should be interpreted broadly. It may include, for example, a fixed connection, a removable connection or an integral connection; a mechanical connection or an electrical connection; a direct interconnection or an interconnection by use of an intermediate medium; or an inner communication of two elements, unless otherwise specified or defined expressly. The specific meaning of the above-mentioned terms in the present disclosure will be understood by those of ordinary skill in the art depending on specific circumstances.

Terms used herein are only for the purpose of describing specific examples without any intention of limiting them. Singular forms such as “a” or “an” are also intended to include plural forms, unless otherwise noted in the context. It is also understood that at least one of terms “include” or “comprise” used herein designates existence of at least one of the stated feature, integer, step, operation, element or assembly without excluding existence or addition of one or more other features, integers, steps, operations, elements, assemblies and/or any combination thereof.

A dynamic random access memory (DRAM) comprises a plurality of memory cells each of which may be formed by a memory capacitor controlled by a transistor.

In some examples, the plurality of memory cells in a memory are arranged in a plane. For example, the plurality of memory cells are located in the same layer. This kind of memory can store data, but it has a large volume and a lower storage density.

In other examples, the plurality of memory cells in a memory are stacked. For example, the plurality of memory cells are located in different layers, and a step structure is disposed in the memory to draw out bit lines corresponding to memory cells in different layers. This kind of memory can increase storage density, but it has a complex process for fabricating the step structure.

The present disclosure provides a method of fabricating a semiconductor device. The semiconductor device may be a DRAM or the like.

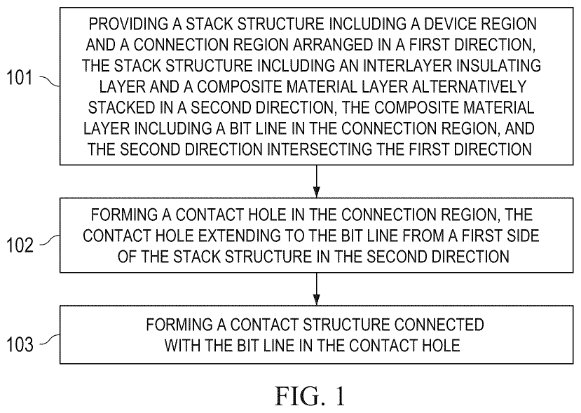

Referring to FIG. 1, a schematic flowchart is shown, which illustrates a method of fabricating a semiconductor device provided by an example of the present disclosure.

As shown in FIG. 1, an example of the present disclosure provides a method of fabricating a semiconductor device, which includes operations 101 to 103 as described in detail below.

In operation 101, a stack structure is provided, wherein the stack structure includes a device region and a connection region arranged in a first direction. The stack structure includes an interlayer insulating layer and a composite material layer alternatively stacked in a second direction, the composite material layer includes a bit line in the connection region, and the second direction intersects the first direction.

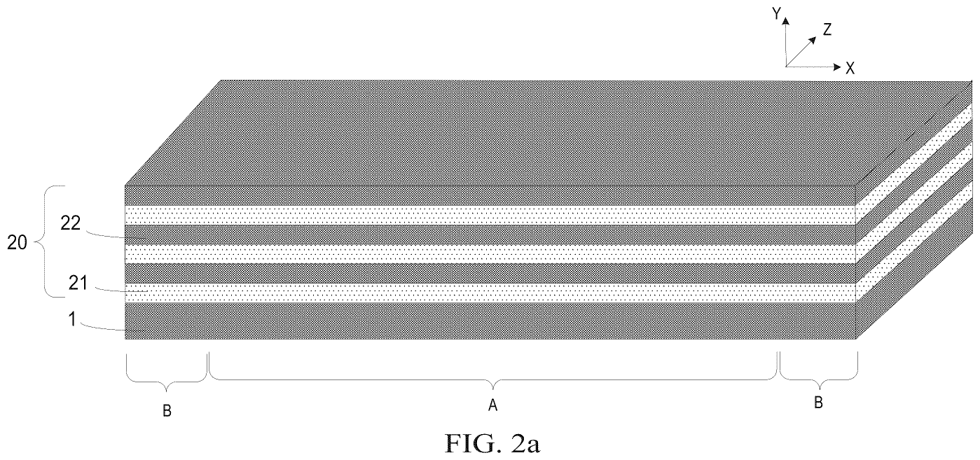

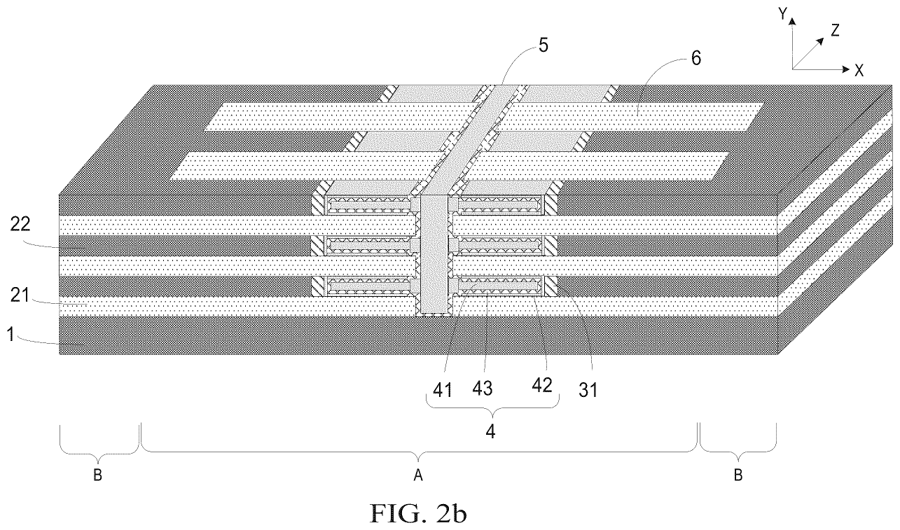

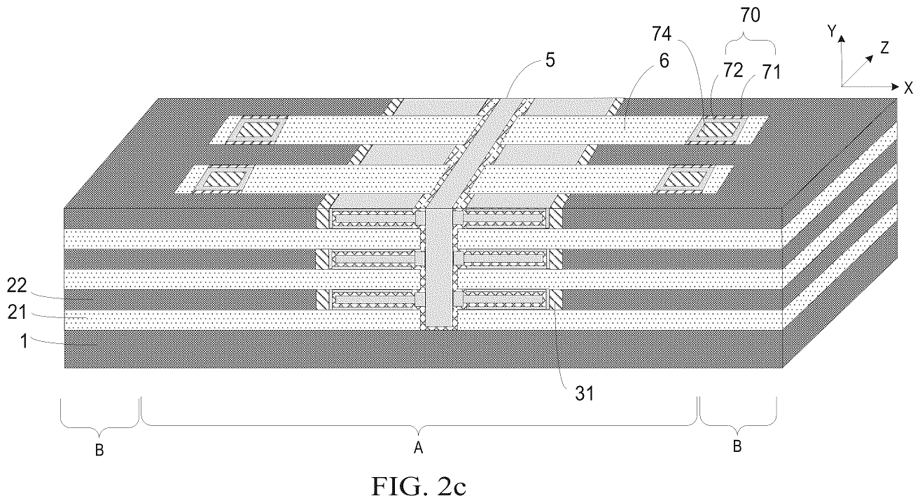

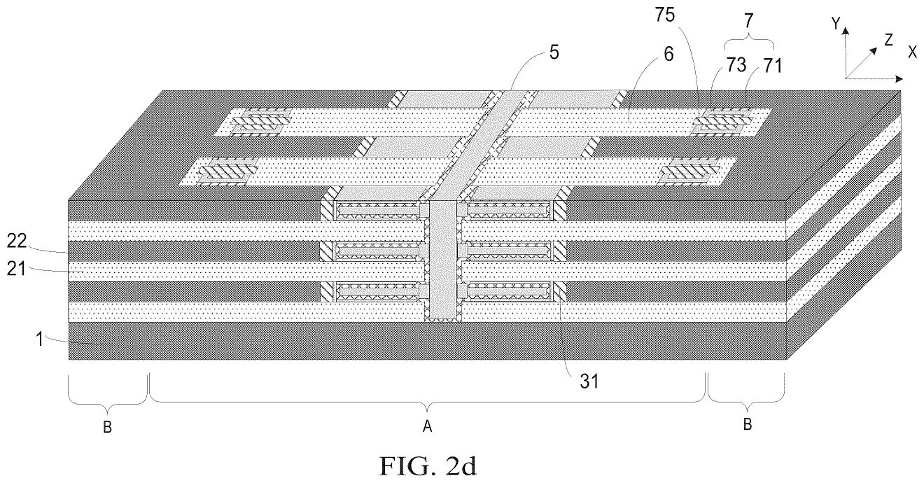

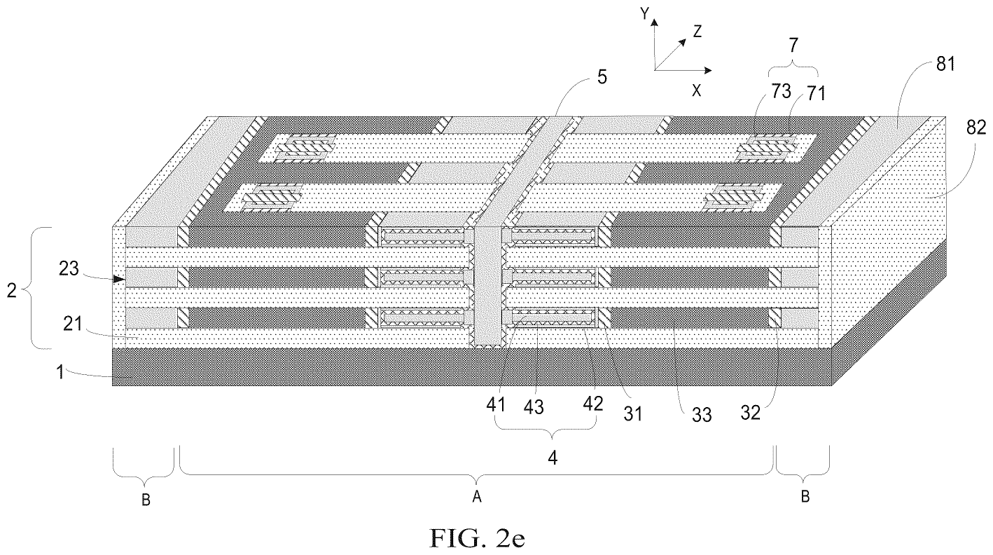

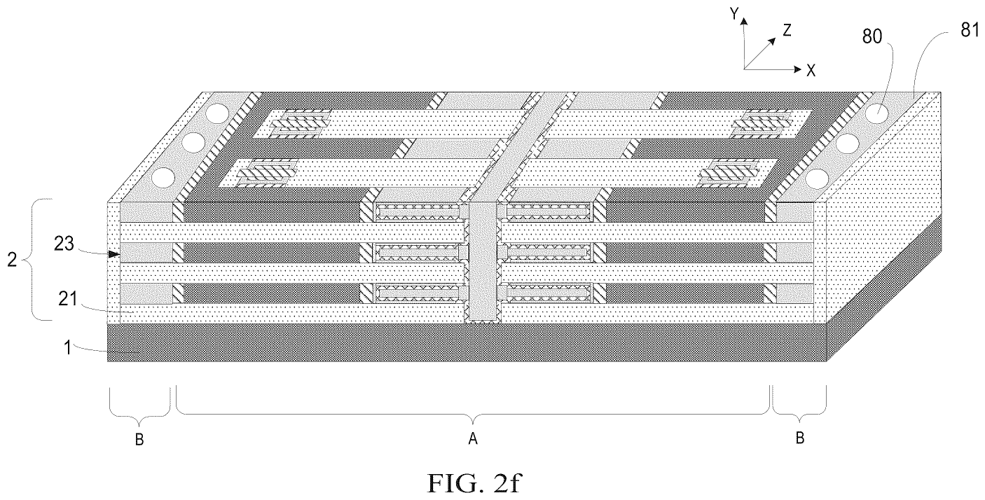

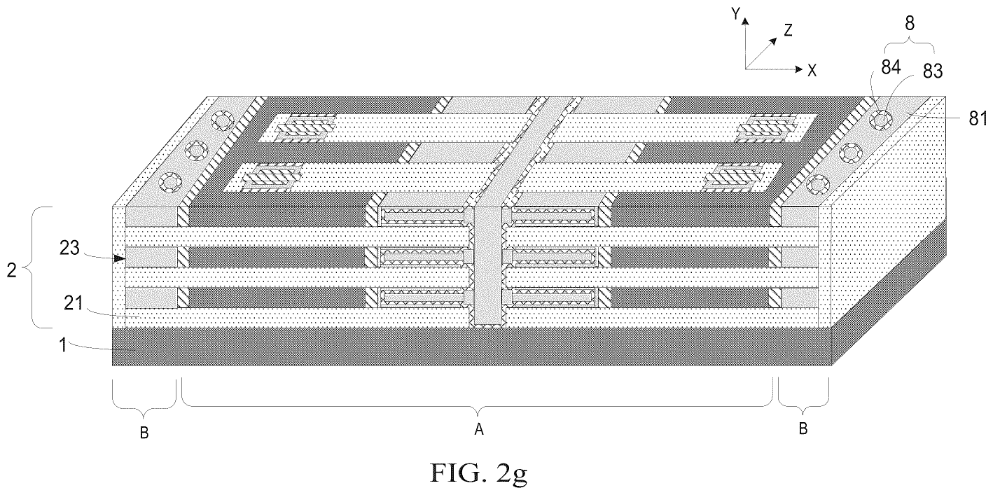

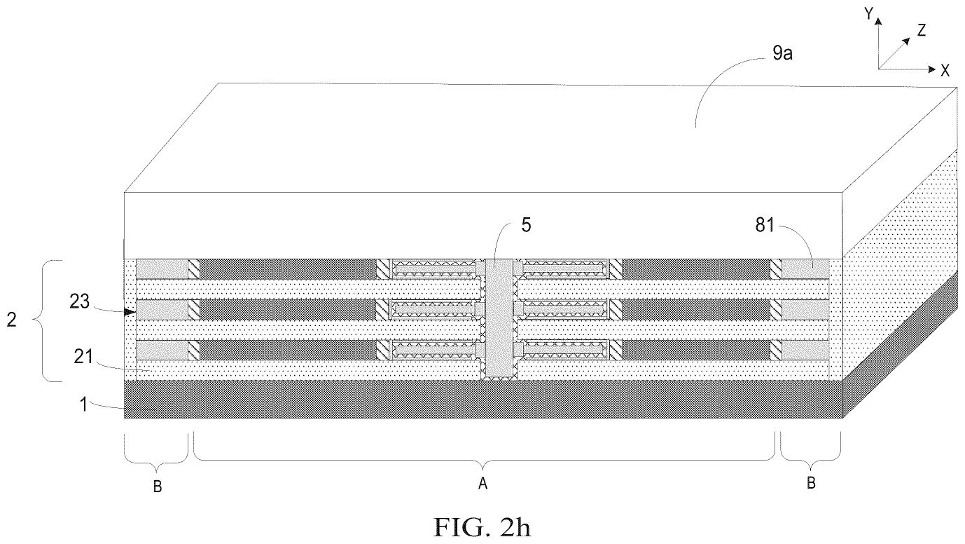

The stack structure may be made from an initial stack structure. For example, the initial stack structure is provided first and then fabricated into the stack structure. As shown in FIG. 2a, the initial stack structure 20 may include a device region A and connection regions B arranged in the first direction X. In an example, as shown in FIG. 2a, the device region A may be located between two connection regions B. A connection region B may also be located between two device region A, which is not limited herein.

The method may further include providing a substrate. As shown in FIG. 2a, substrate 1 is located in the device region A and connection regions B. The substrate 1 may be of a single-layered structure or multi-layered composite structure. The material for substrate 1 may include single crystalline silicon, poly-crystalline silicon, single-crystalline germanium, III-V compound semiconductor materials, II-V compound semiconductor materials or other semiconductor materials. In subsequent fabrication process, it is possible to replace substrate 1 with other layers, or remove the substrate 1 such that the ultimately formed semiconductor device has no substrate 1.

The initial stack structure 20 is located on a side of the substrate 1. For example, the substrate 1 and the initial stack structure 20 are arranged in the second direction Y. The second direction Y intersects the first direction X. For example, the second direction Y is perpendicular to the first direction X. The initial stack structure 20 includes an interlayer insulating layer 21 and an initial material layer 22 stacked alternatively in the second direction Y. There may be a plurality of interlayer insulating layers 21 and there may be a plurality of initial material layers 22. The interlayer insulating layers 21 are located in the device region A and connection regions B, and the initial material layers 22 are located in the device region A and connection regions B. The material for the interlayer insulating layers 21 may include at least one of silicon oxide, silicon nitride, silicon oxynitride, doped silicon oxide, organic silicate glass, or the like. The initial material layers 22 may be semiconductor material layers, and the material for the initial material layers 22 may include at least one of single crystalline silicon, silicon germanium, poly-crystalline silicon, IGZO (indium gallium zinc oxide), N-type oxide semiconductor, or the like.

A spacer layer may be further formed in the device region A. As shown in FIG. 2b, the spacer layer 6 penetrates through the initial stack structure 20 in the second direction Y, and extends in the device region A in the first direction X. The number of the spacer layer 6 may be plurality, and the plurality of spacer layers 6 are arranged in a third direction Z at intervals. The third direction Z intersects the first direction X and the second direction Y, respectively. For example, the third direction Z is perpendicular to the first direction X and the second direction Y, respectively. The material for the spacer layer 6 may include at least one of silicon oxide, silicon nitride, silicon oxynitride, doped silicon oxide, organic silicate glass, or the like.

Next, a capacitor, transistor and plate line (PL) will be formed in the device region A. The capacitor includes a first electrode, a high dielectric constant dielectric layer and a second electrode. The transistor includes a source, a drain, a gate structure and a channel layer. For example, a part of the initial material layer 22 in the device region A is replaced with the source of the transistor and capacitor. When there are multiple initial material layers 22, each initial material layer 22 in the device region A may be replaced with the source of the transistor and capacitor.

In some examples, a first trench (not shown) is formed in the device region A by an etching process, wherein the first trench penetrates through the initial stack structure 20 in the second direction Y, and extends in the third direction Z. When the device region A further includes the spacer layer 6, the first trench also penetrates through the spacer layer 6 in the second direction Y. Next, a part of the initial material layer 22 in the device region A is etched via the first trench to form a first sacrificial gap (not shown) between two adjacent interlayer insulating layers 21 and in the device region A.

As shown in FIG. 2b, a source 31 of a transistor is formed on a surface of an initial material layer 22 exposed by the first sacrificial gap. The material for the source 31 may include silicide or the like.

Next, a capacitor 4 is formed in the first sacrificial gap. In some examples, a second electrode 42 is first formed on the surface of the first sacrificial gap by a thin film deposition process. For example, the second electrode 42 is located on the surface of the source 31, and the surface of the interlayer insulating layer 21 exposed by the first sacrificial gap. Next, a high dielectric constant dielectric layer 43 is formed on the surface of the second electrode 42 and the surface of the first trench. For example, the high dielectric constant dielectric layer 43 is located on the surface of the second electrode 42, the surface of the interlayer insulating layer 21 exposed by the first trench, and the surface of the substrate 1 exposed by the first trench. A conductive material is filled in the first sacrificial gap by a thin film deposition process such that the conductive material filled in the first sacrificial gap forms a first electrode 41. The thin film deposition process may be a physical vapor deposition, chemical vapor deposition, atomic layer deposition, laser assisted deposition or the like.

The method further includes providing a plate line in the device region. As shown in FIG. 2b, while filling the conductive material in the first sacrificial gap, a conductive material is filled in the first trench such that the conductive material filled in the first trench forms a plate line 5.

The first electrode 41, the second electrode 42 and the high dielectric constant dielectric layer 43 form a capacitor 4. For example, the first electrode 41 extends in the first direction X, the high dielectric constant dielectric layer 43 is disposed to surround the first electrode 41, the second electrode 42 is disposed to surround the high dielectric constant dielectric layer 43, the first electrode 41 is connected with the plate line 5, and the second electrode is connected with the source 31. The material for the first electrode 41 may include at least one of tungsten, molybdenum, titanium nitride, doped polysilicon (Doped-Poly), N-type oxide semiconductor, or the like. The material for the second electrode 42 may include at least one of tungsten, molybdenum, titanium nitride, doped polysilicon, N-type oxide semiconductor, or the like. The material for the high dielectric constant dielectric layer 43 includes at least one of hafnium oxide, zirconia hafnium oxide, silicon hafnium oxide, aluminum hafnium oxide, zirconia oxide, or the like. The material for the plate line 5 may include at least one of tungsten, molybdenum, titanium nitride, doped polysilicon, N-type oxide semiconductor, or the like.

The method further includes providing a gate structure in the device region. An initial gate structure 70 is first formed in the device region A, and is located on a side of the source 31 away from the capacitor 4. When the device region A has no spacer layer 6, the initial gate structure 70 penetrates through the initial stack structure 20 in the second direction Y. When the device region A has the spacer layer 6, as shown in FIG. 2c, the initial gate structure 70 is located in the spacer layer 6 and penetrates through the spacer layer 6 in the second direction Y. For example, an opening (not shown) is formed in the spacer layer 6 by an etch process. The opening is located on a side of the source 31 away from the capacitor 4 and penetrates through the spacer layer 6 in the second direction Y. The opening and the initial stack structure 20 are disposed at interval in the first direction X. For example, there is the spacer layer 6 between the opening and the initial stack structure in the first direction X. The opening and the initial stack structure 20 are disposed adjacent to each other in the third direction Z. For example, the width of the opening in the third direction Z is the same as the width of the spacer layer 6 in the third direction Z.

In some examples, as shown in FIG. 2c, surfaces of the initial material layer 22 exposed by the opening are oxidized to form gate insulating layers 71 on two opposite side walls of the opening in the third direction Z, respectively. For example, the gate insulating layers 71 cover the surfaces of the initial stack structure 20 exposed by the opening. Then, initial gate layers 72 are formed on side walls of the opening by a thin film deposition process. For example, the initial gate layers 72 cover surfaces of the spacer layer 6 and the gate insulating layer 71 exposed by the opening. The gate insulating layers 71 and the initial gate layer 72 in the opening form an initial gate structure 70. A filling layer 74 is formed in the opening by a thin film deposition process.

After forming the initial gate structure 70, it may be divided into two gate structures 7. The initial gate structure 70 also may be divided into two gate structures 7 after filling an insulating layer in the second trench. As shown in FIG. 2d, after forming the initial gate structure 70, an isolation layer 75 that penetrates through the initial gate structure 70 in the second direction Y is formed to divide the initial gate layer 72 into two gate layers 73 in one-to-one correspondence with the two gate insulating layers 71, thereby dividing the initial gate structure 70 into two gate structures 7. For example, each gate structure 7 includes a gate layer 73 and a gate insulating layer 71 correspond to the gate layer 73.

The isolation layer 75 may further extend in the first direction X in the spacer layer 6, and the isolation layer 75 may further penetrate through the filling layer 74 in the first direction X. The material for the gate layer 73 may include at least one of tungsten, cobalt, copper, aluminum, doped polysilicon, metal silicide, or the like. The material for the gate insulating layer 71 may include at least one of silicon oxide, silicon nitride, silicon oxynitride, doped silicon oxide, organic silicate glass, or the like. The material for the filling layer 74 may include at least one of silicon oxide, silicon nitride, silicon oxynitride, doped silicon oxide, organic silicate glass, or the like. The material for the isolation layer 75 may include at least one of silicon oxide, silicon nitride, silicon oxynitride, doped silicon oxide, organic silicate glass, or the like.

Then, the initial material layers 22 in the device region A and connection regions B are replaced with drains of transistors and bit lines, respectively. For example, a second trench (not shown) is formed in the connection region B that penetrates through the initial stack structure 20 in the second direction Y, and extends in the third direction Z. A part of initial material layer 22 in the device region A and connection regions B is removed via the second trench to form a second sacrificial gap (not shown) between two adjacent interlayer insulating layers 21, and the second sacrificial gap is in the device region A and connection regions B.

In some examples, as shown in FIG. 2e, a drain 32 of a transistor is formed on a surface of an initial material layer 22 exposed by the second sacrificial gap by a thin film deposition process, wherein the drain 32 is located in the device region A. After forming the drain 32, the initial material layer between the source 31 and drain 32 may serve as a channel layer 33 of the transistor. The channel layer 33 may be compatible with a polysilicon channel and may be of a non-volatile memory medium. Then, a bit line 81 is formed in the second sacrificial gap by a thin film deposition process, and the bit line 81 is located in the connection region B. Then, an insulating layer 82 is filled in the second trench by a thin film deposition process. The material for the drain 32 may include silicide or the like. The material for the insulating layer 82 may include at least one of silicon oxide, silicon nitride, silicon oxynitride, doped silicon oxide, organic silicate glass, or the like. The material for the bit line 81 may include at least one of tungsten, molybdenum, titanium nitride, doped polysilicon, N-type oxide semiconductor, or the like.

As shown in FIG. 2e, after forming the capacitor 4, source 31, drain 32 and bit line 81, the initial material layers 22 in the initial stack structure 20 have been converted into composite material layers 23, and the initial stack structure 20 has been converted into a stack structure 2. For example, the stack structure 2 includes the interlayer insulating layers 21 and composite material layers 23 stacked alternatively in the second direction Y. The composite material layer 23 includes the bit line 81 in the connection region B, the channel layer 33, source 31 and drain 32 in the device region A, and the capacitor 4 in the device region A. The gate structure 7 is located in the device region A and penetrates through the stack structure 2 in the second direction Y. Alternatively, the spacer layer 6 is located in the device region A and penetrates through the stack structure 2 in the second direction Y, and the gate structure 7 is located in the spacer layer 6 and penetrates through the spacer layer 6 in the second direction Y. The plate line 5 penetrates through the stack structure 2 in the second direction Y and extends in the third direction Z, and the plate line 5 is located on a side of the gate structure 7 away from the bit line 81. The channel layer 33 and the gate structure 7 are arranged in the third direction Z, the drain 32 is located between the channel layer 33 and the bit line 81, the drain 32 is connected with the bit line 81, and the source 31 is located between the channel layer 33 and the plate line 5. The capacitor 4 is located between the plate line 5 and the source 31 and, is connected with the plate line 5 and the source 31, respectively. The capacitor 4 includes a first electrode 41 extending in the first direction X, a high dielectric constant dielectric layer 43 disposed around the first electrode 41, and a second electrode 42 disposed around the high dielectric constant dielectric layer 43. The first electrode 41 is connected with the plate line 5, and the second electrode is connected with the source 31.

In operation 102, a contact hole is formed in the connection region, the contact hole extending from a first side of the stack structure to the bit line in the second direction.

After forming the stack structure 2, the stack structure 2 includes a plurality of composite material layers 23 each of which includes a bit line 81 located in the connection region B. The number of the contact hole 80 may also be plurality, and the number of the contact hole 80 may be the same as the number of the composite material layer 23 such that different contact holes 80 extend to bit lines 81 in different composite material layers 23 from the first side of the stack structure 2 in the second direction Y. For example, the connection region B has a plurality of the contact holes 80 formed therein, and the plurality of the contact holes 80 are disposed in one-to-one correspondence with a plurality of the bit lines 81, and each of the contact holes 80 extends to the corresponding bit line 81 from the first side of the stack structure 2 in the second direction Y.

In a first implementation, the contact hole 80 extends to a corresponding bit line 81 from a side of the stack structure 2 away from the substrate 1 in the second direction Y. For example, the first side of the stack structure 2 is the side of the stack structure 2 away from the substrate 1. As shown in FIG. 2f, a plurality of contact holes 80 are formed in the connection region B by an etch process, and each contact hole 80 extends to the corresponding bit line 81 from the side of the stack structure 2 away from the substrate 1 in the second direction Y.

In operation 103, a contact structure is formed in the contact hole, and the contact structure is connected with the bit line.

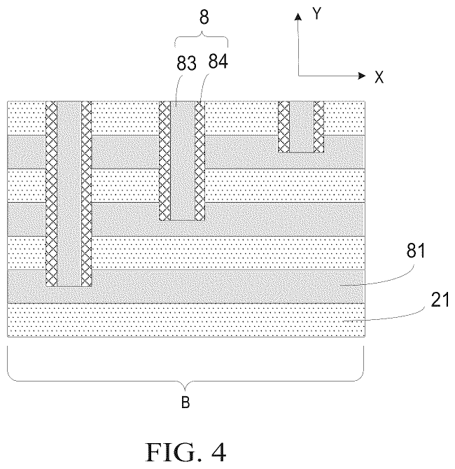

As shown in FIG. 2g, a contact structure 8 is formed in the contact hole 80 by a thin film deposition process, and the contact structure 8 is connected with the bit line 81 in the composite material layer 23. When the numbers of the contact hole 80 and composite material layer 23 are both a plurality and the plurality of contact holes 80 are disposed in one-to-one correspondence with the plurality of composite material layers 23, as shown in FIG. 4, the contact structure 8 in each contact hole 80 extends to the bit line 81 in the corresponding composite material layer 23 from the side of the stack structure 2 away from the substrate 1 in the second direction Y, such that each contact structure 8 is connected with the corresponding bit line 81.

The contact structure 8 includes a conductive layer 83 and an isolation layer 84 disposed around the conductive layer 83, and the conductive layer 83 is connected with the bit line 81. For example, the conductive layer 83 extends to the bit line 81 from the first side of the stack structure 2 in the second direction Y, so as to be connected with the bit line 81, and the isolation layer 84 covers side walls of the conductive layer 83. The material for the conductive layer 83 may include at least one of tungsten, molybdenum, titanium nitride, doped polysilicon, N-type oxide semiconductor, or the like. The material for the isolation layer 84 may include at least one of silicon oxide, silicon nitride, silicon oxynitride, doped silicon oxide, organic silicate glass, or the like.

Further, after the operation of forming the contact structure in the contact hole, the method further includes: bonding a first peripheral device on the first side of the stack structure, wherein the first peripheral device is connected with the contact structure, the gate structure and the plate line, respectively.

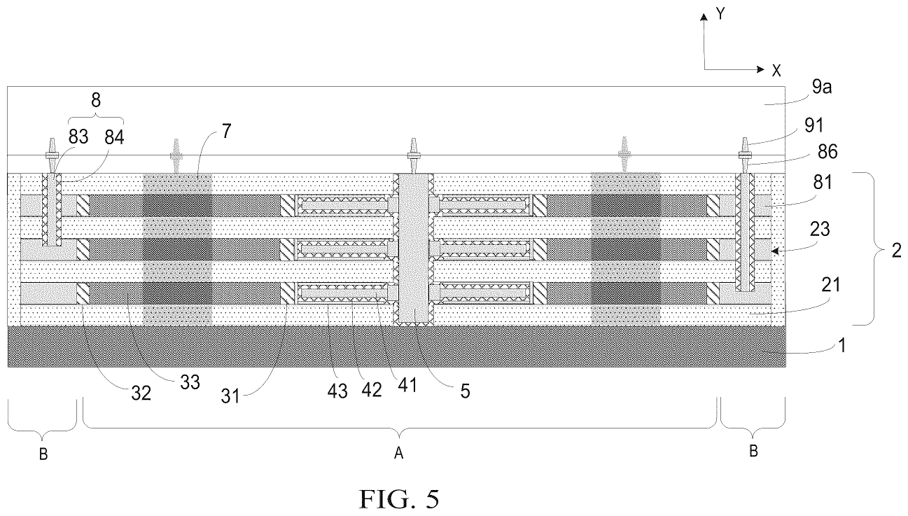

As shown in FIG. 2h, a first peripheral device 9a is bonded on the side of the stack structure 2 away from the substrate 1 such that the first peripheral device 9a is connected with the contact structure 8, the gate structure 7 and the plate line 5 respectively. For example, as shown in FIG. 5, it is possible to form first bonding interfaces 86 on a side of the contact structure 8 away from the substrate 1, a side of the gate structure 7 away from the substrate 1 and a side of the plate line 5 away from the substrate 1 respectively, such that the contact structure 8, the gate structure 7 and the plate line 5 are connected with the corresponding first bonding interfaces 86, respectively. The first peripheral device 9a includes a second bonding interface 91 corresponding to the first bonding interface 86. The first bonding interface 86 is connected with the corresponding second bonding interface 91 such that the contact structure 8, the gate structure 7 and the plate line 5 are connected with the first peripheral device 9a via the first bonding interfaces 86 and the second bonding interfaces 91 successively, thereby implementing the bonding of the stack structure 2 and the first peripheral device 9a. The material for the first bonding interfaces 86 may include at least one of tungsten, molybdenum, titanium nitride, doped polysilicon, N-type oxide semiconductor, or the like. The material for the second bonding interfaces 91 may include at least one of tungsten, molybdenum, titanium nitride, doped polysilicon, N-type oxide semiconductor, or the like.

The first peripheral device 9a may comprise a CMOS (Complementary Metal Oxide Semiconductor), a FPGA (Field-Programmable Gate Array), a CPU (Central Processing Unit), or the like, and may also comprise other devices that can be bonded with the stack structure 2, which is not limited herein.

In a second implementation, the substrate 1 is removed, and the contact hole 80 extends to the corresponding bit line 81 in the second direction Y from a side of the stack structure 2 from which the substrate 1 is removed. For example, the first side of the stack structure 2 is the side of the stack structure 2 from which the substrate 1 is removed.

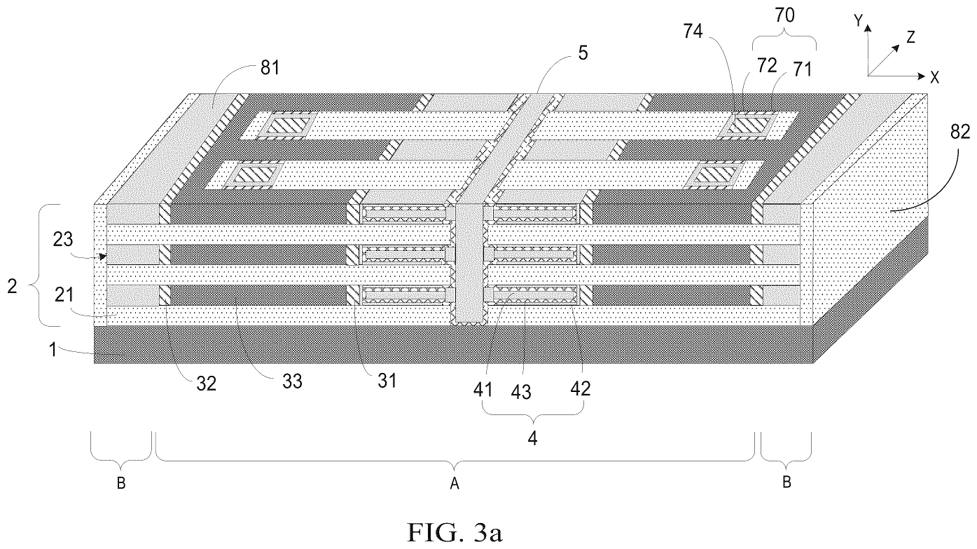

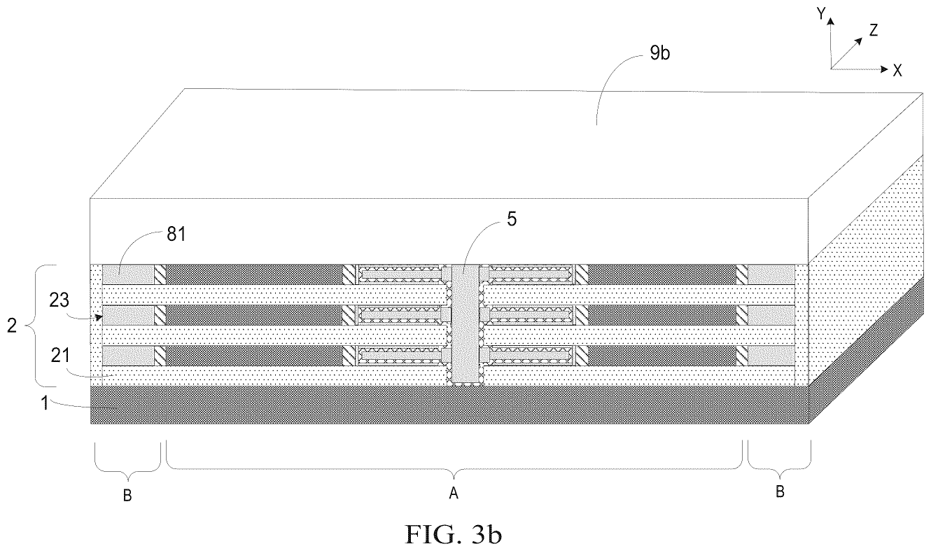

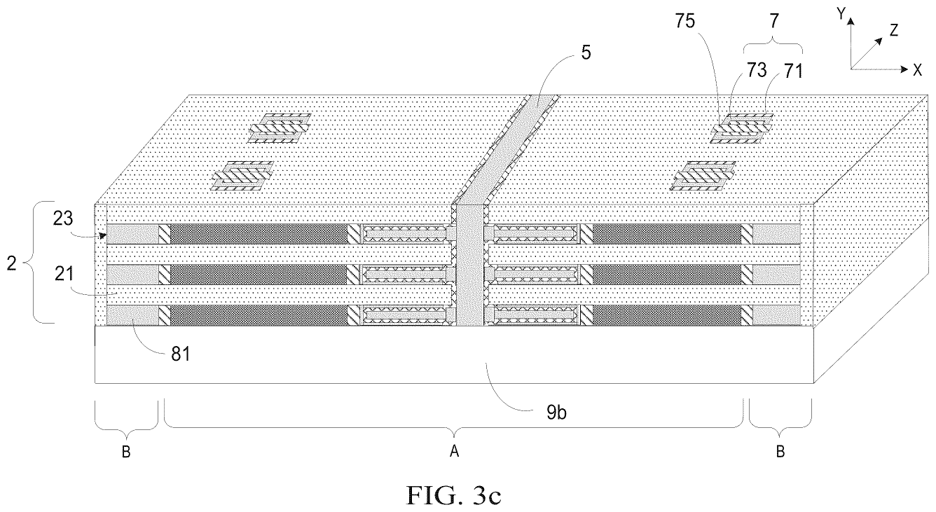

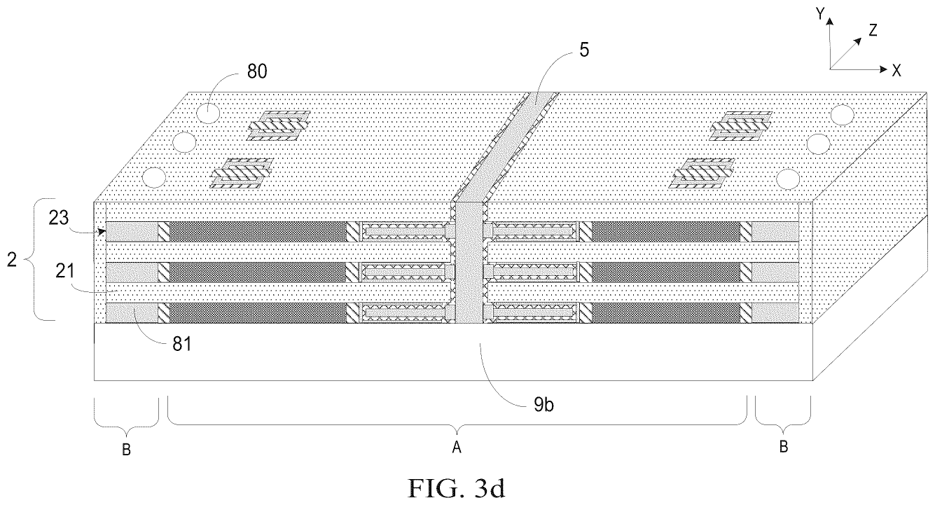

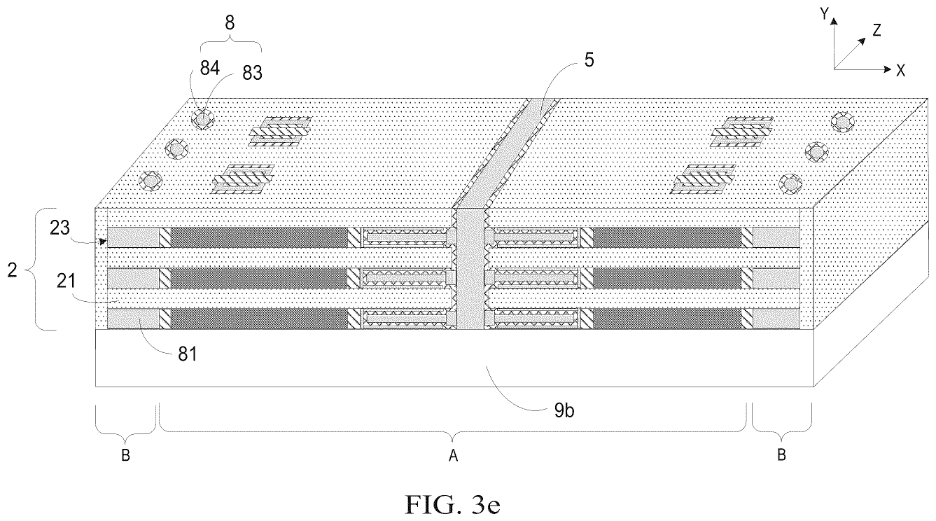

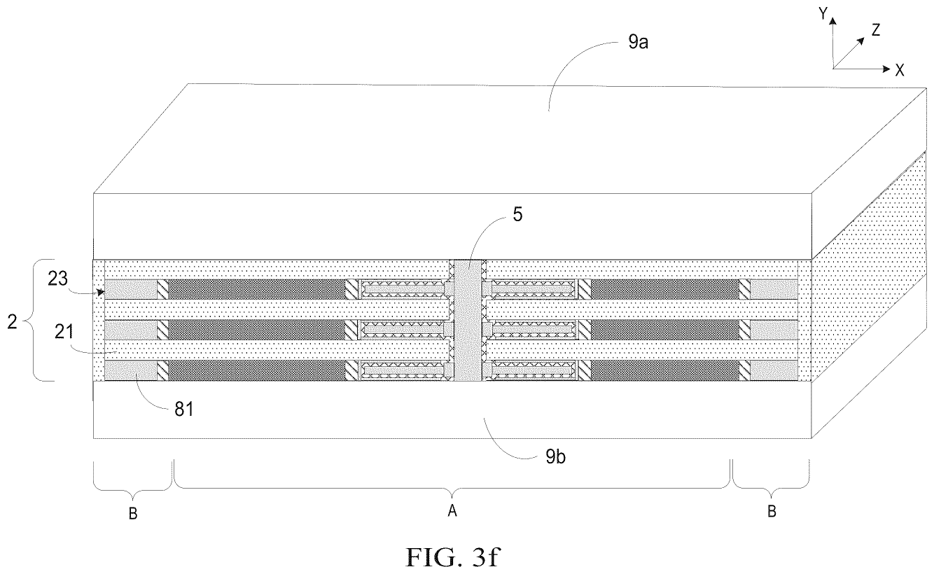

As shown in FIG. 3a, after forming the source 31 of the transistor, the capacitor 4, the plate line 5 and the initial gate structure 70, the drain 32 of the transistor, the bit line 81 and the insulating layer 82 are formed first to convert the initial material layers 22 in the initial stack structure 20 into composite material layers 23 and convert the initial stack structure 20 into the stack structure 2.

Next, contact hole 80 is formed in the connection region B. For example, the forming the contact hole in the connection region in the operation 102 includes: removing the substrate; and forming the contact hole in the connection region, wherein the first side of the stack structure is the side of the stack structure from which the substrate is removed.

Because the substrate 1 needs to be removed, a carrier wafer (the carrier wafer will be removed in subsequent processes. For example, the finally completed semiconductor device has no carrier wafer) or a peripheral device is first bonded on a second side of the stack structure 2 (the side of the stack structure 2 away from the substrate 1).

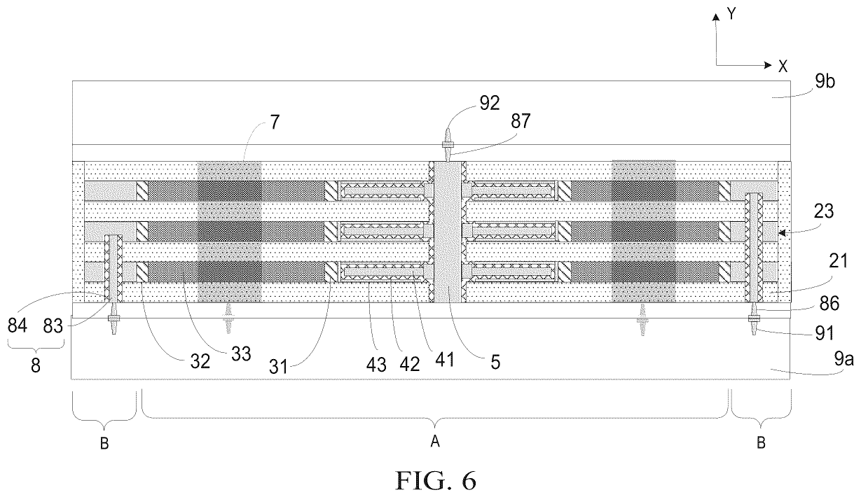

When bonding the peripheral device on the second side of the stack structure 2, the peripheral device is connected with an least one of the initial gate structure 70 or the plate line 5. In some examples, as shown in FIG. 3b, a second peripheral device 9b is bonded on the second side of the stack structure 2 so that the second peripheral device 9b is connected with the plate line 5. For example, as shown in FIG. 6, a third bonding interface 87 may be formed on the second side of the stack structure 2 so that the plate line 5 is connected with the third bonding interface 87. The second peripheral device 9b includes a fourth bonding interface 92 corresponding to the third bonding interface 87. The third bonding interface 87 is connected with the corresponding fourth bonding interface 92 such that the plate line 5 is connected with the second peripheral device 9b via the third bonding interface 87 and the fourth bonding interface 92 successively, thereby implementing the bonding of the stack structure 2 and the second peripheral device 9b. The material for the third bonding interface 87 may include at least one of tungsten, molybdenum, titanium nitride, doped polysilicon, N-type oxide semiconductor, or the like. The material for the fourth bonding interface 92 may include at least one of tungsten, molybdenum, titanium nitride, doped polysilicon, N-type oxide semiconductor, or the like.

The second peripheral device 9b may comprise a CMOS, a FPGA, a CPU, or the like, and may also comprise other devices that can be bonded with the stack structure 2, which is not limited herein.

After bonding the carrier wafer or the peripheral device on the second side of the stack structure 2, the entire structure is inverted. Before the inversion, the carrier wafer or the peripheral device faces upward and the substrate 1 faces downward; and after the inversion, the carrier wafer or the peripheral device faces downward and the substrate 1 faces upward. As shown in FIG. 3c, the substrate 1 is removed after the inversion to expose the initial gate structure 70. Then, an isolation layer 75 that penetrates through the initial gate structure 70 in the second direction Y is formed to divide the initial gate structure 70 into two gate structures 7. For example, each gate structure 7 includes a gate layer 73 and a gate insulating layer 71 correspond to the gate layer 73. The isolation layer 75 may further extend in the first direction X such that the isolation layer 75 may further penetrate through the filling layer 74 in the second direction Y and extend in the first direction X in the spacer layer 6.

As shown in FIG. 3d, a plurality of contact holes 80 are formed in the connection region B by an etch process, and each contact hole 80 extends to the corresponding bit line 81 in the second direction Y from a side of the stack structure 2 from which the substrate 1 is removed. As shown in FIG. 3e, a contact structure 8 is formed in the contact hole 80 by a thin film deposition process and the contact structure 8 is connected with a bit line 81 in the composite material layer 23. When the numbers of the contact hole 80 and composite material layer 23 are both a plurality and the plurality of contact holes 80 are disposed in one-to-one correspondence with the plurality of composite material layers 23, as shown in FIG. 4, the contact structure 8 in each contact hole 80 extends to the bit line 81 in the corresponding composite material layer 23 from a side of the stack structure 2 away from the substrate 1 in the second direction Y such that each contact structure 8 is connected with the corresponding bit line 81.

The contact structure 8 includes a conductive layer 83 and an isolation layer 84 disposed around the conductive layer 83, and the conductive layer 83 is connected with the bit line 81. For example, the conductive layer 83 extends to the bit line 81 from the first side of the stack structure 2 in the second direction Y so as to be connected with the bit line 81, and the isolation layer 84 covers side walls of the conductive layer 83.

If the carrier wafer is bonded on the second side of the stack structure 2, then after the operation of forming the contact structure in the contact hole, the method further includes: bonding a first peripheral device on the first side of the stack structure, wherein the first peripheral device is connected with the contact structure, the gate structure and the plate line, respectively.

For example, it is possible to form first bonding interfaces on a side of the contact structure 8 away from the carrier wafer, a side of the gate structure 7 away from the carrier wafer and a side of the plate line 5 away from the carrier wafer, respectively such that the contact structure 8, the gate structure 7 and the plate line 5 are connected with corresponding first bonding interfaces respectively. The first peripheral device includes second bonding interfaces corresponding to the first bonding interfaces. The first bonding interfaces are connected with the corresponding second bonding interfaces to implement the bonding of the stack structure and the first peripheral device. After the stack structure 2 and the first peripheral device are bonded, it is possible to remove the carrier wafer.

If the second peripheral device 9b is boned on the second side of the stack structure 2, then the method further includes: bonding the first peripheral device 9a on the first side of the stack structure 2, with the contact structure 8 connected with the first peripheral device 9a, the gate structure 7 connected with the first peripheral device 9a or the second peripheral device 9b, and the plate line 5 connected with the first peripheral device 9a or the second peripheral device 9b. That is, the contact structure 8 is connected with the first peripheral device 9a, and at least one of the gate structure 7 or the plate line 5 is connected with the second peripheral device 9b. Namely, both the gate structure 7 and the plate line 5 may be connected with the second peripheral device 9b, or the gate structure 7 is connected with the second peripheral device 9b and the plate line 5 is connected with the first peripheral device 9a, or the gate structure 7 is connected with the first peripheral device 9a and the plate line 5 is connected with the second peripheral device 9b.

In some examples, as shown in FIG. 3f, the first peripheral device 9a is bonded on the first side of the stack structure 2 (i.e., the side of the stack structure 2 away from the second peripheral device 9b). As shown in FIG. 6, it is possible to form first bonding interfaces 86 on a side of the contact structure 8 away from the second peripheral device 9b and a side of the gate structure 7 away from the second peripheral device 9b, respectively such that the contact structure 8 and the gate structure 7 are connected with corresponding first bonding interfaces 86 respectively. The first peripheral device 9a includes second bonding interfaces 91 corresponding to the first bonding interfaces 86. The first bonding interface 86 is connected with the corresponding second bonding interface 91 such that the contact structure 8 and the gate structure 7 are connected with the first peripheral device 9a via the first bonding interfaces 86 and the second bonding interfaces 91 successively, thereby implementing the bonding of the stack structure 2 and the first peripheral device 9a.

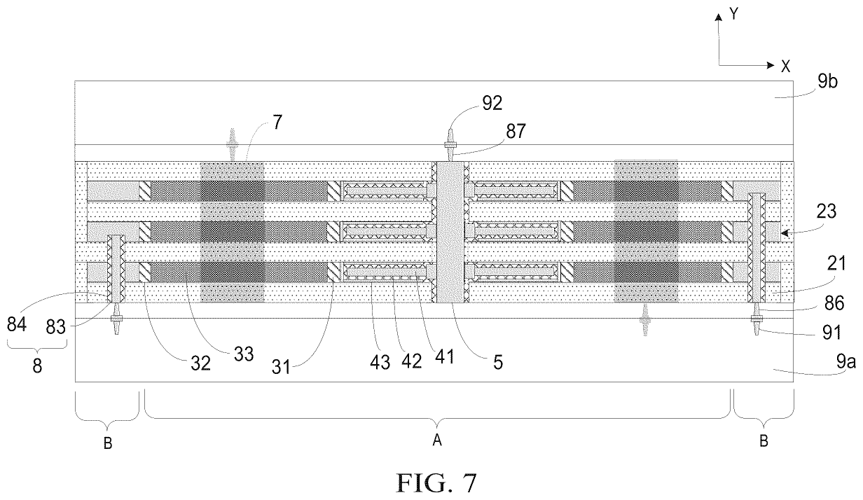

In other examples, as shown in FIG. 7, the contact structure 8 is connected with the first peripheral device 9a, and the gate structure 7 and the plate line 5 are connected with the second peripheral device 9b. For example, the stack structure 2 has first bonding interface 86 corresponding to the contact structure 8 on the first side, and the contact structure 8 is connected with the corresponding first bonding interface 86. The first peripheral device 9a includes second bonding interface 91 corresponding to the first bonding interface 86. The first bonding interface 86 is connected with the corresponding second bonding interface 91 such that the contact structure 8 is connected with the first peripheral device 9a via the first bonding interface 86 and the second bonding interface 91 successively, thereby implementing the bonding of the stack structure 2 and the first peripheral device 9a.

The stack structure 2 has third bonding interfaces 87 corresponding to the plate line 5 and the gate structure 7 on the second side, and the plate line 5 and the gate structure 7 are connected with the corresponding third bonding interfaces 87. The second peripheral device 9b includes a fourth bonding interface 92 corresponding to the third bonding interface 87. The third bonding interface 87 is connected with the corresponding fourth bonding interface 92 such that the plate line 5 and the gate structure 7 are connected with the second peripheral device 9b via the third bonding interfaces 87 and the fourth bonding interfaces 92 successively, thereby implementing the bonding of the stack structure 2 and the second peripheral device 9b.

The second peripheral device 9b and the first peripheral device 9a may be devices with same functions or different functions.

The fabrication method of the semiconductor device as provided by some examples of the present disclosure can provide a stack structure including a device region and a connection region arranged in the first direction and including an interlayer insulating layer and a composite material layer stacked alternatively in the second direction such that memory cells in the device region are stacked in the second direction to reduce the volume of the semiconductor device and improve the storage density. In addition, the composite material layer includes a bit line in the connection region, the contact structure is located in the connection region, and the contact structure extends to the bit line from the first side of the stack structure in the second direction and is connected with the bit line. Thus, the stack structure in the connection region is not fabricated with a step structure, thereby simplifying the fabrication process.

Some examples of the present disclosure provide a semiconductor device that can be formed with the above-described method of fabricating a semiconductor device. The semiconductor device may be a dynamic random access memory, or the like.

As shown in FIGS. 5 to 7, the semiconductor device includes a stack structure 2 including a device region A and connection region B arranged in the first direction X. A device region A may be located between two connection regions B, and a connection region B may also be located between two device regions A, which is not limited herein.

The stack structure 2 includes an interlayer insulating layer 21 and a composite material layer 23 stacked alternatively in the second direction Y. There may be a plurality of the interlayer insulating layers 21 and there may be a plurality of the composite material layers 23. The second direction Y intersects the first direction X. For example, the second direction Y is perpendicular to the first direction X. The material for the interlayer insulating layer 21 may include at least one of silicon oxide, silicon nitride, silicon oxynitride, doped silicon oxide, organic silicate glass, or the like.

The composite material layer 23 include a bit line 81 located in the connection region B. When the stack structure 2 includes a plurality of the composite material layers 23, each of the composite material layers 23 includes the bit line 81. The material for the bit line 81 may include at least one of tungsten, molybdenum, titanium nitride, doped polysilicon, N-type oxide semiconductor, or the like.

The semiconductor device further includes a contact structure 8 in the connection region B. The contact structure 8 extends to the bit line 81 from the first side of the stack structure 2 in the second direction Y, and is connected with the bit line 81. The numbers of contact structures 8 may be plurality. That is, the semiconductor device may include a plurality of contact structures 8 disposed in one-to-one correspondence with the plurality of composite material layers 23. As shown in FIG. 4, different contact structures 8 extend to different bit lines 81 from the first side of the stack structure 2 in the second direction Y. That is, each contact structure 8 extends to the bit line 81 in the corresponding composite material layer 23 from the first side of the stack structure 2 in the second direction Y, such that each contact structure 8 is connected with the corresponding bit line 81.

The contact structure 8 includes a conductive layer 83 and an isolation layer 84 disposed around the conductive layer 83, and the conductive layer 83 is connected with the bit line 81. For example, the conductive layer 83 extends to the bit line 81 from the first side of the stack structure 2 in the second direction Y, so as to be connected with the bit line 81, and the isolation layer 84 covers side walls of the conductive layer 83. The material for the conductive layer 83 may include at least one of tungsten, molybdenum, titanium nitride, doped polysilicon, N-type oxide semiconductor, or the like. The material for the isolation layer 84 may include at least one of silicon oxide, silicon nitride, silicon oxynitride, doped silicon oxide, organic silicate glass, or the like.

As shown in FIGS. 2g and 3e, the semiconductor device may further include a gate structure 7 in the device region A. The gate structure 7 may penetrate through the stack structure 2 in the second direction Y. Alternatively, the semiconductor device may further include a spacer layer 6 located in the device region A. The spacer layer 6 penetrates through the stack structure 2 in the second direction Y and extends in the first direction X, and the gate structure 7 is located in the spacer layer 6 and penetrates through the spacer layer 6 in the second direction Y.

Every two gate structures 7 may be a group, and the two gate structures 7 in a group are disposed at interval and face to face in the third direction Z. The third direction Z intersects the first direction X and the second direction Y respectively. For example, the third direction Z is perpendicular to the first direction X and the second direction Y respectively. A group of gate structures 7 are disposed adjacent to the stack structure 2 in the third direction Z, and an isolation layer 75 is disposed between two gate structures 7 in a group to isolate the two gate structures 7.

The gate structure 7 includes a gate 73 penetrating through the stack structure 2 in the second direction Y and a gate insulating layer 71 between the gate 73 and the stack structure 2. The material for the gate layer 73 may include at least one of tungsten, cobalt, copper, aluminum, doped polysilicon, metal silicide, or the like. The material for the gate insulating layer 71 may include at least one of silicon oxide, silicon nitride, silicon oxynitride, doped silicon oxide, organic silicate glass, or the like. The material for the spacer layer 6 may include at least one of silicon oxide, silicon nitride, silicon oxynitride, doped silicon oxide, organic silicate glass, or the like. The material for the isolation layer 75 may include at least one of silicon oxide, silicon nitride, silicon oxynitride, doped silicon oxide, organic silicate glass, or the like.

The semiconductor device further includes a plate line 5 in the device region A. The plate line 5 penetrates through the stack structure 2 in the second direction Y and extends in the third direction Z, and the plate line 5 is located on a side of the gate structure 7 away from the bit line 81. The material for the plate line 5 may include at least one of tungsten, molybdenum, titanium nitride, doped polysilicon, N-type oxide semiconductor, or the like.

The composite material layer 23 further includes a channel layer 33, a source 31 and a drain 32 in the device region A. The channel layer 33 and the gate structure 7 are arranged in the third direction Z, the drain 32 is located between the channel layer 33 and the bit line 81, the drain 32 is connected with the bit line 81, and the source 31 is located between the channel layer 33 and the plate line 5. The material for the source 31 may include silicide or the like. The material for the drain 32 may include silicide or the like. The material for the channel layer 33 may include at least one of single crystalline silicon, silicon germanium, poly-crystalline silicon, IGZO, N-type oxide semiconductor, or the like. The channel layer 33 may be compatible with a polysilicon channel, and may be of a non-volatile memory medium.

Each composite material layer 23 includes corresponding channel layer 33, source 31 and drain 32, and the corresponding channel layer 33, source 31 and drain 32 together with the corresponding gate structure 7 may form a transistor.

The composite material layer 23 further includes a capacitor 4 in the device region A. The capacitor 4 is located between the plate line 5 and the source 31, and is connected with the plate line 5 and the source 31 respectively. Each composite material layer 23 includes a capacitor 4, and each capacitor is connected with a corresponding transistor. Each capacitor, together with its corresponding transistor form a memory cell.

For example, the capacitor 4 includes a first electrode 41 extending in the first direction X, a high dielectric constant dielectric layer 43 disposed around the first electrode 41, and a second electrode 42 disposed around the high dielectric constant dielectric layer 43; the first electrode is connected with the plate line, and the second electrode is connected with the source. The material for the first electrode 41 may include at least one of tungsten, molybdenum, titanium nitride, doped polysilicon, N-type oxide semiconductor, or the like. The material for the second electrode 42 may include at least one of tungsten, molybdenum, titanium nitride, doped polysilicon, N-type oxide semiconductor, or the like. The material for the high dielectric constant dielectric layer 43 includes at least one of hafnium oxide, zirconia hafnium oxide, silicon hafnium oxide, aluminum hafnium oxide, zirconia oxide, or the like.

In an implementation, as shown in FIG. 5, the semiconductor device further includes a first peripheral device 9a bonded on the first side of the stack structure 2, and the first peripheral device 9a is connected with the contact structure 8, the gate structure 7 and the plate line 5, respectively.

The first side of the stack structure 2 may be the front side or back side of the stack structure 2. That is, the first peripheral device 9a may be located on the front side or the back side of the stack structure 2. When the first side of the stack structure 2 is the front side of the stack structure 2, the semiconductor device may further include a substrate 1 located in the device region A and connection region B. As shown in FIG. 5, the stack structure 2 is located on a side of the substrate 1, and the front side of the stack structure 2 is a side of the stack structure 2 away from the substrate 1 (the substrate 1 is located on the back side of the stack structure 2). For example, the first peripheral device 9a may be located on a side of the stack structure 2 away from the substrate 1. The back side of the stack structure 2 is opposite the front side of the stack structure 2. When bonding the first peripheral device 9a on the back side of the stack structure 2, the stack structure 2 has no substrate 1 on the back side. The substrate 1 may be of a single-layered structure or a multi-layered composite structure. The material for the substrate 1 may include single crystalline silicon, poly-crystalline silicon, single-crystalline germanium, III-V compound semiconductor materials, II-V compound semiconductor materials or other semiconductor materials.

For example, as shown in FIG. 5, the stack structure 2 has the first bonding interfaces 86 corresponding to the contact structure 8, the gate structure 7 and the plate line 5 on the first side, and the contact structure 8, the gate structure 7 and the plate line 5 are connected with the corresponding first bonding interfaces 86, respectively. The first peripheral device 9a includes a second bonding interfaces 91 corresponding to the first bonding interface 86. The first bonding interface 86 is connected with the corresponding second bonding interface 91 such that the contact structure 8, the gate structure 7 and the plate line 5 are connected with the first peripheral device 9a via the first bonding interfaces 86 and the second bonding interfaces 91, thereby implementing the bonding of the stack structure 2 and the first peripheral device 9a. The material for the first bonding interface 86 may include at least one of tungsten, molybdenum, titanium nitride, doped polysilicon, N-type oxide semiconductor, or the like. The material for the second bonding interface 91 may include at least one of tungsten, molybdenum, titanium nitride, doped polysilicon, N-type oxide semiconductor, or the like.

The first peripheral device 9a may comprise a CMOS, a FPGA, a CPU, or the like.

In another implementation, as shown in FIG. 6, the semiconductor device further includes a first peripheral device 9a and a second peripheral device 9b. The first peripheral device 9a is bonded on the first side of the stack structure 2, the second peripheral device 9b is bonded on the second side of the stack structure 2, the second side of the stack structure 2 is opposite the first side, the contact structure 8 is connected with the first peripheral device 9a, the gate structure 7 is connected with the first peripheral device 9a or the second peripheral device 9b, and the plate line 5 is connected with the first peripheral device 9a or the second peripheral device 9b.

The first side of the stack structure 2 may be the front side or back side of the stack structure 2. If the first side of the stack structure 2 is the front side of the stack structure 2, then the second side of the stack structure 2 is the back side of the stack structure 2. For example, the first peripheral device 9a is located on the front side of the stack structure 2 and the second peripheral device 9b is located on the back side of the stack structure 2; and if the first side of the stack structure 2 is the back side of the stack structure 2, then the second side of the stack structure 2 is the front side of the stack structure 2. For example, the first peripheral device 9a is located on the back side of the stack structure 2 and the second peripheral device 9b is located on the front side of the stack structure 2.

The contact structure 8 is connected with the first peripheral device 9a, and at least one of the gate structure 7 or the plate line 5 may be connected with the second peripheral device 9b. For example, both the gate structure 7 and the plate line 5 may be connected with the second peripheral device 9b, or the gate structure 7 is connected with the second peripheral device 9b and the plate line 5 are connected with the first peripheral device 9a, or the gate structure 7 is connected with the first peripheral device 9a and the plate line 5 is connected with the second peripheral device 9b.

In some examples, as shown in FIG. 6, the contact structure 8 and the gate structure 7 are connected with the first peripheral device 9a, and the plate line 5 is connected with the second peripheral device 9b. For example, as shown in FIG. 6, the stack structure 2 has the first bonding interfaces 86 corresponding to the contact structure 8 and the gate structure 7 on the first side, and the contact structure 8 and the gate structure 7 are connected with the corresponding first bonding interfaces 86, respectively. The first peripheral device 9a includes a second bonding interface 91 corresponding to the first bonding interface 86. The first bonding interface 86 is connected with the corresponding second bonding interface 91 such that the contact structure 8 and the gate structure 7 are connected with the first peripheral device 9a via the first bonding interfaces 86 and the second bonding interfaces 91 successively, thereby implementing the bonding of the stack structure 2 and the first peripheral device 9a.

The stack structure 2 has a third bonding interface 87 corresponding to the plate line 5 on the second side, and the plate line 5 is connected with the corresponding third bonding interface 87. The second peripheral device 9b includes a fourth bonding interface 92 corresponding to the third bonding interface 87. The third bonding interface 87 is connected with the corresponding fourth bonding interface 92 such that the plate line 5 is connected with the second peripheral device 9b via the third bonding interface 87 and the fourth bonding interface 92 successively, thereby implementing the bonding of the stack structure 2 and the second peripheral device 9b. The material for the third bonding interface 87 may include at least one of tungsten, molybdenum, titanium nitride, doped polysilicon, N-type oxide semiconductor, or the like. The material for the fourth bonding interface 92 may include at least one of tungsten, molybdenum, titanium nitride, doped polysilicon, N-type oxide semiconductor, or the like.

In some other examples, as shown in FIG. 7, the contact structure 8 is connected with the first peripheral device 9a, and the gate structure 7 and the plate line 5 are connected with the second peripheral device 9b. For example, the stack structure 2 has a first bonding interface 86 corresponding to the contact structure 8 on the first side, and the contact structure 8 is connected with the corresponding first bonding interface 86. The first peripheral device 9a includes a second bonding interface 91 corresponding to the first bonding interface 86. The first bonding interface 86 is connected with the corresponding second bonding interface 91 such that the contact structure 8 is connected with the first peripheral device 9a via the first bonding interface 86 and the second bonding interface 91 successively, thereby implementing the bonding of the stack structure 2 and the first peripheral device 9a.

The stack structure 2 has third bonding interfaces 87 corresponding to the plate line 5 and the gate structure 7 on the second side, and the plate line 5 and the gate structure 7 are connected with the corresponding third bonding interfaces 87. The second peripheral device 9b includes a fourth bonding interface 92 corresponding to the third bonding interface 87. The third bonding interface 87 is connected with the corresponding fourth bonding interface 92 such that the plate line 5 and the gate structure 7 are connected with the second peripheral device 9b via the third bonding interfaces 87 and the fourth bonding interfaces 92 successively, thereby implementing the bonding of the stack structure 2 and the second peripheral device 9b.

The second peripheral device 9b may comprise CMOS, SRAM, DRAM, FPGA, CPU, or the like. The second peripheral device 9b and the first peripheral device 9a may be devices with same functions or different functions.

The semiconductor device as provided by some examples of the present disclosure can provide a stack structure including a device region and a connection region arranged in the first direction and including an interlayer insulating layer and a composite material layer stacked alternatively in the second direction such that memory cells in the device region are stacked in the second direction to reduce the volume of the semiconductor device and improve the storage density. In addition, the composite material layer includes a bit line in the connection region, the contact structure is located in the connection region, and the contact structure extends to the bit line from the first side of the stack structure in the second direction and is connected with the bit line. Thus, the stack structure in the connection region does not need to be fabricated with a step structure, thereby simplifying the fabrication process.

In some examples, the above-described semiconductor device comprises a memory device such as DRAM.

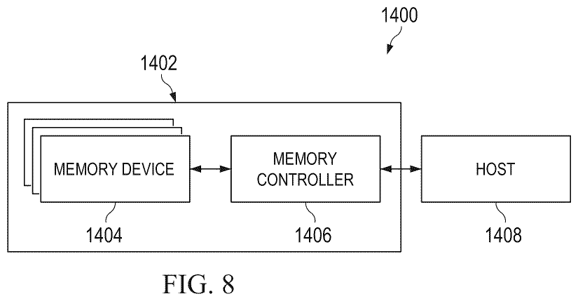

FIG. 8 is a block diagram of a system having a memory device according to an example of the present disclosure. Referring to FIG. 8, the system 1400 includes a memory system 1402. The memory system 1402 has one or more memory devices 1404 and a memory controller 1406. The memory device 1404 is any memory device as described previously, and is configured to store data. The memory controller 1406 is coupled to the memory device 1404, and is configured to control the memory device 1404.

As shown in FIG. 8, in some examples, the system 1400 further includes a host 1408 coupled to the memory controller 1406.

The system 1400 can comprise a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic device having memory device therein. The host 1408 may comprise a processor of the electronic device such as a central processing unit (CPU) or a system-on-chip (SoC), for example an application processor (AP). The host 1408 may be configured to transmit or receive data to or from the memory device 1404.

The memory device 1404 may be any of the memory devices disclosed in the present disclosure. In some implementations, each memory device 1404 includes a memory cell array and a peripheral circuit for the memory cell array, wherein the peripheral circuit and the memory cell array are stacked on each other in different planes.

According to some implementations, the memory controller 1406 is coupled to the memory device 1404 and the host 1408, and is configured to control the memory device 1404. The memory controller 1406 can manage data stored in the memory device 1404 and communicate with the host 1408. In some implementations, the memory controller 1406 is designed for operating in a low duty-cycle environment like a secure digital (SD) card, a compact Flash (CF) card, a universal serial bus (USB) Flash drive, or other medium for use in electronic devices, such as a personal computer, a digital camera, a mobile phone, or the like. In some implementations, the memory controller 1406 is designed for operating in a high duty-cycle environment such as a SSD or an embedded multi-media-card (eMMC) used as data storage for a mobile device, such as a smartphone, a tablet, a laptop computer, or the like, and an enterprise storage array. The memory controller 1406 may be configured to control operations of the memory device 1404, such as read, erase, and program operations. In some implementations, the memory controller 1406 is configured to control the memory cell array through a first peripheral circuit and a second peripheral circuit. The memory controller 1406 may also be configured to manage various functions with respect to the data stored or to be stored in the memory device 1404 including, but not limited to bad-block management, garbage collection, logical-to-physical address conversion, wear leveling, or the like. In some implementations, the memory controller 1406 is further configured to process an error correction code (ECC) with respect to the data read from or written to the memory device 1404. Any other suitable functions may be performed by the memory controller 1406 as well, for example, formatting the memory device 1404. The memory controller 1406 may communicate with an external device (e.g., the host 1408) according to a particular communication protocol. For example, the memory controller 1406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, or the like.

The memory controller 1406 and one or more memory devices 1404 may be integrated into various types of memory device, for example, be included in the same package, such as a universal Flash storage (UFS) package or an eMMC package. That is, the memory system 1402 may be implemented and packaged into different types of end electronic products. In some examples, the memory controller 1406 and multiple memory devices 1404 may be integrated into an SSD.

The present disclosure has been described above with reference to various examples, however the examples are not intended to limit the present disclosure. Variations and modifications to the present disclosure may be made by those of ordinary skills in the art without departing from the spirit and scope of the present disclosure, and accordingly, a scope of the present disclosure is only defined by the claims.

What is claimed is:

1. A fabrication method of a semiconductor device, comprising:
providing a stack structure comprising a device region and a connection region arranged in a first direction, the stack structure comprising an interlayer insulating layer and a composite material layer alternatively stacked in a second direction, the composite material layer comprising a bit line in the connection region, and the second direction intersecting the first direction;
forming a contact hole in the connection region, the contact hole extending to the bit line from a first side of the stack structure in the second direction; and
forming a contact structure connected with the bit line in the contact hole.

2. The fabrication method of claim 1, wherein the contact structure comprises a conductive layer and an isolation layer disposed around the conductive layer, wherein the conductive layer is connected with the bit line; and
wherein the conductive layer extends to the bit line from the first side of the stack structure in the second direction, and the isolation layer covers side walls of the conductive layer.

3. The fabrication method of claim 1, wherein the stack structure comprises a plurality of the composite material layers, and each of the composite material layers comprises the bit line; and
the connection region has a plurality of the contact holes formed therein and disposed in one-to-one correspondence with a plurality of the bit lines, and each of the contact holes extends to a corresponding bit line from the first side of the stack structure in the second direction.

4. The fabrication method of claim 1, further comprising:
providing a substrate, the stack structure being on a side of the substrate, and the first side of the stack structure being a side of the stack structure away from the substrate.

5. The fabrication method of claim 1, further comprising: providing a substrate, the stack structure being on a side of the substrate, and
wherein the forming the contact hole in the connection region comprises:
removing the substrate; and
forming the contact hole in the connection region, the first side of the stack structure being a side of the stack structure from which the substrate is removed.

6. The fabrication method of claim 1, further comprising:
providing a gate structure in the device region, the gate structure penetrating through the stack structure in the second direction.

7. The fabrication method of claim 6, further comprising:
providing a plate line in the device region, the plate line penetrating through the stack structure in the second direction and extending in a third direction and being located on a side of the gate structure away from the bit line, and the third direction intersecting the second direction and the first direction.

8. The fabrication method of claim 7, further comprising:
after the forming the contact structure in the contact hole, bonding a first peripheral device on the first side of the stack structure, wherein the first peripheral device is connected with the contact structure, the gate structure and the plate line, respectively.

9. The fabrication method of claim 7, further comprising:
bonding a first peripheral device on the first side of the stack structure, and bonding a second peripheral device on a second side of the stack structure, wherein the second side of the stack structure is opposite the first side, the contact structure is connected with the first peripheral device, the gate structure is connected with the first peripheral device or the second peripheral device, and the plate line is connected with the first peripheral device or the second peripheral device.

10. A semiconductor device, comprising:
a stack structure comprising a device region and a connection region arranged in a first direction, the stack structure comprising an interlayer insulating layer and a composite material layer alternatively stacked in a second direction, the composite material layer comprising a bit line in the connection region, and the second direction intersecting the first direction; and
a contact structure in the connection region, the contact structure extending to the bit line from a first side of the stack structure in the second direction and connected with the bit line.

11. The semiconductor device of claim 10, wherein the contact structure comprises a conductive layer and an isolation layer disposed around the conductive layer, wherein the conductive layer is connected with the bit line.

12. The semiconductor device of claim 11, wherein the conductive layer extends to the bit line from the first side of the stack structure in the second direction, and the isolation layer covers side walls of the conductive layer.

13. The semiconductor device of claim 10, wherein the stack structure comprises a plurality of the composite material layers, each of the composite material layers comprises the bit line, the semiconductor device comprises a plurality of the contact structures disposed in one-to-one correspondence with a plurality of the bit lines, and each of the contact structures extends to a corresponding bit line from the first side of the stack structure in the second direction and is connected with the corresponding bit line.

14. The semiconductor device of claim 10, further comprising a gate structure in the device region, wherein the gate structure penetrates through the stack structure in the second direction; and
wherein the gate structure comprises a gate and a gate insulating layer, wherein the gate penetrates through the stack structure in the second direction, and the gate insulating layer is located between the gate and the stack structure.

15. The semiconductor device of claim 14, further comprising a plate line in the device region, wherein the plate line penetrates through the stack structure in the second direction, extends in a third direction, and is located on a side of the gate structure away from the bit line, and the third direction intersects the second direction and the first direction.

16. The semiconductor device of claim 15, further comprising a first peripheral device, wherein the first peripheral device is bonded on the first side of the stack structure, and the first peripheral device is connected with the contact structure, the gate structure and the plate line, respectively.

17. The semiconductor device of claim 15, further comprising a first peripheral device and a second peripheral device,
wherein the first peripheral device is bonded on the first side of the stack structure, the second peripheral device is bonded on a second side of the stack structure, the second side of the stack structure is opposite the first side, the contact structure is connected with the first peripheral device, the gate structure is connected with the first peripheral device or the second peripheral device, and the plate line is connected with the first peripheral device or the second peripheral device.

18. The semiconductor device of claim 15, wherein the composite material layer further comprises a channel layer, a source and a drain in the device region, wherein the channel layer and the gate structure are arranged in a third direction, the third direction intersects the second direction and the first direction, the drain is located between the channel layer and the bit line, the drain is connected with the bit line, and the source is located between the channel layer and the plate line.

19. The semiconductor device of claim 18, wherein:
the composite material layer further comprises a capacitor in the device region,
the capacitor is located between the plate line and the source, and is connected with the plate line and the source, respectively,
the capacitor comprises a first electrode extending in the first direction, a high dielectric constant dielectric layer disposed around the first electrode, and a second electrode disposed around the high dielectric constant dielectric layer, and
the first electrode is connected with the plate line, and the second electrode is connected with the source.

20. A memory system, comprising:
a memory comprising a semiconductor device, the semiconductor device comprising:
a stack structure comprising a device region and a connection region arranged in a first direction, the stack structure comprising an interlayer insulating layer and a composite material layer alternatively stacked in a second direction, the composite material layer comprising a bit line in the connection region, and the second direction intersecting the first direction; and
a contact structure in the connection region, the contact structure extending to the bit line from a first side of the stack structure in the second direction and connected with the bit line; and
a controller electrically connected with the memory.
